(19) United States
(12) Patent Application Publication
(10) Pub. No.: US 2026/0334181 A1
(43) Pub. Date: Oct. 22, 2026

(54) METHODS OF DEPOSITING MOLYBDENUM

(71) Applicant: Applied Materials, Inc., Santa Clara, CA (US)

(72) Inventors: Yao Xu, San Jose, CA (US); Xi Cen, San Jose, CA (US); Kai Wu, Palo Alto, CA (US); Rongjun Wang, Dublin, CA (US)

(73) Assignee: Applied Materials, Inc., Santa Clara, CA (US)

(21) Appl. No.: 19/648,144

(22) Filed: Apr. 15, 2026

Related U.S. Application Data
(60) Provisional application No. 63/792,077, filed on Apr. 21, 2025.

(51) Int. Cl. H10W 20/00; C23C 16/04; C23C 16/06; C23C 16/455; C23C 16/50; H10P 14/43

(52) U.S. Cl. CPC H10W 20/033; C23C 16/045; C23C 16/06; C23C 16/45536; C23C 16/50; H10P 14/43; H10W 20/056

(57) ABSTRACT

Methods of depositing molybdenum (Mo) are disclosed. The methods include depositing molybdenum (Mo) on a substrate including a top surface and at least one feature including a sidewall surface and a bottom surface. The molybdenum (Mo) is deposited to fill the at least one feature and the molybdenum (Mo) is substantially free of seams and/or voids or free of seams and/or voids

### CROSS-REFERENCE TO RELATED APPLICATIONS

This application claims priority to United States Provisional Application No. 63/792,077, filed Apr. 21, 2025, the entire disclosure of which is hereby incorporated by reference herein.

### TECHNICAL FIELD

Embodiments of the disclosure generally relate to the field of semiconductor device manufacturing. More particularly, embodiments of the disclosure are directed to methods of depositing molybdenum for semiconductor device manufacture.

### BACKGROUND

As circuit integration increases, there is an enhanced need for greater uniformity and process control regarding layer thickness. As a result, various technologies have been developed to deposit layers on substrates in a cost-effective manner, while maintaining control over the characteristics of the layer. Chemical vapor deposition (CVD) is one of the most common deposition processes employed for depositing layers on a substrate.

A variant of CVD that demonstrates excellent step coverage is cyclical deposition or atomic layer deposition (ALD). ALD employs chemisorption techniques to deliver precursor molecules on a substrate surface in sequential cycles. An ALD cycle includes exposing the substrate surface to a first precursor, a purge gas, a second precursor, and the purge gas. The first and second precursors react to form a product compound as a film on the substrate surface. The ALD cycle is repeated to form the layer to a desired thickness.

The advancing complexity of advanced microelectronic devices is placing stringent demands on currently used deposition techniques. Molybdenum and molybdenum-based films have attractive material and conductive properties. These films have been proposed and tested for applications from front-end to back-end parts of semiconductor devices.

While not wishing to be bound by any particular theory or principle, it is believed that molybdenum cannot be deposited and grown directly on a dielectric surface, and that molybdenum can be deposited on a metallic surface.

Molybdenum films may be used as low resistivity electrical connections in the form of vertical interconnects and/or horizontal interconnects through which current flows, as vias between adjacent metal layers, and as contacts between a first metal layer and the devices on a substrate. As device dimensions shrink to the angstrom (Å) scale with high aspect ratios, such as greater than or equal to 20:1, achieving void-free, high-quality metal contact fills becomes increasingly challenging. The exponential rise in resistivity at scaled pitches further complicates material selection for interconnects and contacts.

CVD and ALD, as well as plasma-enhanced deposition processes, such as plasma-enhanced chemical vapor deposition (PECVD) and plasma-enhanced atomic layer deposition (PEALD), have been employed to deposit molybdenum in substrate features, e.g., a trench having a sidewall surface and a bottom surface.

The low ion/radical density of the plasma in the harder-to reach areas in the feature lead to formation of an amorphous molybdenum layer having small grains on the bottom surface. Additionally, there may be a large amount of impurities within the feature, and/or the amorphous molybdenum layer, due to the inability of the plasma to treat harder-to-reach areas within the feature. The amorphous molybdenum layer also has higher contact resistance than a crystalline molybdenum layer. In attempting to deposit molybdenum on top of the amorphous molybdenum layer on the bottom surface, due to the presence of impurities, the deposited molybdenum layer that fills the feature may include seams and/or voids, which degrades electrical performance. It has also been found that these plasma-enhanced molybdenum deposition processes are unable to effectively coat bow-in or re-entrant structures.

Some currently employed molybdenum deposition processes include selectively depositing a molybdenum layer directly on the bottom surface of a feature, e.g., a trench by thermal chemical vapor deposition (CVD). In some examples, the thermal CVD process for selectively depositing the molybdenum layer directly on the bottom surface of the feature, e.g., the trench, includes using molybdenum pentachloride (MoCl₅) as a precursor, reduced by hydrogen (H₂). However, this thermal CVD process simultaneously deposits and etches molybdenum and can result in a narrow process window for MoCl₆ to H₂ ratio. The reaction by-products of MoCl₆ and H₂, e.g., HF and MoClₓ, accumulate on the sidewall surface of the feature and cause selectivity loss, resulting in a molybdenum layer having increased resistivity.

Accordingly, there is a need for methods of depositing molybdenum that provide improved film quality and improved film conformality to meet advancing semiconductor device manufacturing requirements.

### SUMMARY

One or more embodiments of the disclosure are directed to a deposition method comprising: conformally depositing a liner layer comprising molybdenum (Mo) directly on a substrate including a top surface and at least one feature including a sidewall surface and a bottom surface. In some embodiments, conformally depositing the liner layer comprises a plasma-enhanced deposition process to form the liner layer along the sidewall surface and the bottom surface. In some embodiments, the liner layer has a thickness of greater than or equal to 50 Å. The deposition method further includes conformally depositing a molybdenum (Mo) layer directly on the liner layer to fill the at least one feature. In some embodiments, conformally depositing the molybdenum (Mo) layer comprises a thermal chemical vapor deposition (CVD) process, and the molybdenum (Mo) layer is substantially free of seams and/or voids.

Additional embodiments of the disclosure are directed to a deposition method comprising: forming a liner layer comprising molybdenum (Mo) directly on a substrate including a top surface and at least one feature including a sidewall surface and a bottom surface. In some embodiments, forming the liner layer comprises a plasma-enhanced deposition process. In some embodiments, the liner layer has a thickness in a range of from 15 Å to less than 50 Å. The deposition method further includes depositing a gapfill layer comprising molybdenum (Mo) directly on the liner layer in bottom-up fashion to fill a portion of the at least one feature; and conformally depositing a molybdenum (Mo) layer directly on the gapfill layer. In some embodiments, the molybdenum (Mo) layer is formed on a top surface of the gapfill layer and on the top surface of the substrate. In some embodiments, each of the gapfill layer and the molybdenum (Mo) layer is substantially free of seams and/or voids.

Further embodiments of the disclosure are directed to a deposition method comprising: forming a liner layer comprising molybdenum (Mo) directly on a substrate including a top surface and at least one feature including a sidewall surface and a bottom surface. In some embodiments, forming the liner layer comprises a plasma-enhanced deposition process. In some embodiments, the liner layer has a thickness of less than 15 Å. The deposition method further includes depositing a gapfill layer comprising molybdenum (Mo) directly on the liner layer in bottom-up fashion to fill the at least one feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended Drawings. It is to be noted, however, that the appended Drawings illustrate only typical embodiments of the present disclosure and are therefore not to be considered limiting of its scope, for the disclosure may admit to other equally effective embodiments.

FIG. 1A illustrates a process flow diagram of a deposition method in accordance with one or more embodiments of the present disclosure;

FIG. 1B illustrates a cross-sectional schematic view of a substrate including a top surface and at least one feature including a sidewall surface and a bottom surface in accordance with one or more embodiments of the present disclosure;

FIG. 1C illustrates a cross-sectional schematic view of the substrate of FIG. 1B after conformally depositing a liner layer on the top surface and along the sidewall surface and the bottom surface in accordance with one or more embodiments of the present disclosure;

FIG. 1D illustrates a cross-sectional schematic view of the substrate of FIG. 1C after conformally depositing a molybdenum (Mo) layer directly on the liner layer to fill a portion of the at least one feature in accordance with one or more embodiments of the present disclosure;

FIG. 1E illustrates a cross-sectional schematic view of the substrate of FIG. 1D after conformally depositing the molybdenum (Mo) layer directly on the liner layer to fill the at least one feature in accordance with one or more embodiments of the present disclosure;

FIG. 2A illustrates a process flow diagram of a deposition method in accordance with one or more embodiments of the present disclosure;

FIG. 2B illustrates a cross-sectional schematic view of a substrate including a top surface and at least one feature including a sidewall surface and a bottom surface in accordance with one or more embodiments of the present disclosure;

FIG. 2C illustrates a cross-sectional schematic view of the substrate of FIG. 2B after depositing a liner layer on the top surface, the sidewall surface, and the bottom surface in accordance with one or more embodiments of the present disclosure;

FIG. 2D illustrates a cross-sectional schematic view of the substrate of FIG. 2C after depositing a gapfill layer directly on the liner layer in bottom-up fashion to fill a portion of the at least one feature in accordance with one or more embodiments of the present disclosure;

FIG. 2E illustrates a cross-sectional schematic view of the substrate of FIG. 2D after conformally depositing a molybdenum (Mo) layer directly on the gapfill layer in accordance with one or more embodiments of the present disclosure;

FIG. 3A illustrates a process flow diagram of a deposition method in accordance with one or more embodiments of the present disclosure;

FIG. 3B illustrates a cross-sectional schematic view of a substrate including a top surface and at least one feature including a sidewall surface and a bottom surface in accordance with one or more embodiments of the present disclosure;

FIG. 3C illustrates a cross-sectional schematic view of the substrate of FIG. 3B after forming a liner layer on the top surface, the sidewall surface, and the bottom surface in accordance with one or more embodiments of the present disclosure;

FIG. 3D illustrates a cross-sectional schematic view of the substrate of FIG. 3C after depositing a gapfill layer directly on the liner layer in bottom-up fashion to fill a portion of the at least one feature in accordance with one or more embodiments of the present disclosure; and

FIG. 3E illustrates a cross-sectional schematic view of the substrate of FIG. 3D after depositing the gapfill layer directly on the liner layer in bottom-up fashion to fill the at least one feature in accordance with one or more embodiments of the present disclosure.

### DETAILED DESCRIPTION

Before describing embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as "beneath," "below," "lower," "above," "upper" and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as "below" or "beneath" other elements or features would then be oriented "above" the other elements or features. Thus, the exemplary term "below" may encompass both an orientation of above and below. The device may be otherwise oriented (rotated 90 degrees or at other orientations) and the spatially relative descriptors used herein interpreted accordingly.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to "one embodiment," "some embodiments," "certain embodiments," "one or more embodiments," or "an embodiment" means that a particular feature, structure, material, or characteristic described in connection with the embodiment is included in at least one embodiment of the disclosure. Thus, the appearances of the phrases such as "in one embodiment," "in some embodiments," "in certain embodiments," "in one or more embodiments," or "in an embodiment" in various places throughout this specification are not necessarily referring to the same embodiment of the disclosure. Furthermore, the particular features, structures, materials, or characteristics may be combined in any suitable manner in one or more embodiments.

As used in this specification and the appended claims, the term "substrate" or "wafer" refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A "substrate" as used herein, refers to any substrate or material surface formed on a substrate upon which film processing is performed during a fabrication process. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term "substrate surface" is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term "feature" refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term "on" indicates that there is direct contact between elements. The term "directly on" indicates that there is direct contact between elements with no intervening elements.

As used herein, the term "in situ" refers to processes that are all performed in the same processing chamber or within different processing chambers that are connected as part of an integrated processing system, such that each of the processes are performed without an intervening vacuum break. As used herein, the term "ex situ" refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species that can react with the substrate surface.

As used herein, the term "chemical vapor deposition" refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, "substantially simultaneously" means that most of the duration of the first reactive species exposure overlaps with the second reactive species exposure.

"Atomic layer deposition" or "cyclical deposition" as used herein refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially.

As used herein, the terms "purge" or "purging" each independently include any suitable purge process that removes unreacted precursor/reactant, reaction products, and by-products from the process region (e.g., a processing chamber). The suitable purge process includes moving the substrate through a gas curtain to a portion or sector of the processing region that contains none or substantially none of the precursor/reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the processing chamber for a time duration in a range of from 0 seconds to 30 seconds, 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term "substantially" used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the terms "thermal" or "thermal process(es)" each independently refer to a deposition technique that does not involve the use of plasma. As used herein, the term "plasma" refers to a composition have ionically charged species and uncharged neutral and radical species.

Plasma-enhanced CVD (PECVD) methods add a plasma exposure to traditional CVD methods. In some PECVD methods, a hydrogen source is provided as the plasma. The primary benefit of PECVD methods is the relatively low substrate temperature, e.g., less than or equal to 600 °C, during processing.

Plasma-enhanced ALD (PEALD) methods add a plasma exposure to traditional ALD methods. In some PEALD methods, a hydrogen source is provided as the plasma. The primary benefit of PEALD methods is the relatively low substrate temperature, e.g., less than or equal to 600 °C, during processing.

One or more of the layers deposited on the substrate or substrate surface are continuous. As used herein, the term "continuous" refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced ALD (PEALD) are conformal. As used herein, as will be understood by the skilled artisan, a layer/film which is “conformal” or "conformally deposited" refers to a layer/film where the thickness is about the same throughout. A layer/film which is conformal varies in thickness by less than or equal to about 5 %, 2 %, 1 % or 0.5 %.

The low ion/radical density of the plasma in the harder-to reach areas in the feature lead to formation of an amorphous molybdenum layer having small grains on the bottom surface. Additionally, there may be a large amount of impurities within the feature, and/or the amorphous molybdenum layer, due to the inability of the plasma to treat harder-to-reach areas within the feature. The amorphous molybdenum layer also has higher contact resistance than a crystalline molybdenum layer. In attempting to deposit molybdenum on top of the amorphous molybdenum layer on the bottom surface, due to the presence of impurities, the deposited molybdenum layer that fills the feature may include seams and/or voids, which degrades electrical performance. It has also been found that these plasma-enhanced molybdenum deposition processes are unable to effectively coat bow-in or re-entrant structures.

Some currently employed molybdenum deposition processes include selectively depositing a molybdenum layer directly on the bottom surface of a feature, e.g., a trench by thermal chemical vapor deposition (CVD). In some examples, the thermal CVD process for selectively depositing the molybdenum layer directly on the bottom surface of the feature, e.g., the trench, includes using molybdenum pentachloride (MoCl₅) as a precursor, reduced by hydrogen (H₂). However, this thermal CVD process simultaneously deposits and etches molybdenum and can result in a narrow process window for MoCl₆ to H₂ ratio. The reaction by-products of MoCl₆ and H₂, e.g., HF and MoClₓ, accumulate on the sidewall surface of the feature and cause selectivity loss, resulting in a molybdenum layer having increased resistivity.

Embodiments of the present disclosure are directed to provide methods of depositing molybdenum (Mo) as part of a semiconductor device manufacturing process and/or a microelectronic device manufacturing process, e.g., for semiconductor device and microelectronic device applications. Some embodiments advantageously provide molybdenum deposition methods with tunable incubation control. Some embodiments advantageously provide methods of depositing molybdenum with controlled grain structure. Some embodiments advantageously provide epitaxial single-grain molybdenum growth for reduced resistivity. Some embodiments advantageously provide large-grain molybdenum growth for reduced resistivity. Advantageously, the disclosed methods of depositing molybdenum which provide controlled grain structure provide optimized electrical performance of semiconductor device and microelectronic device applications.

Some embodiments provide methods of depositing molybdenum (Mo) on a substrate comprising a feature, such as, for example, at least one vertically extending feature and/or at least one laterally extending feature. Some embodiments advantageously provide methods of depositing molybdenum (Mo) without seams and/or voids.

One or more embodiments are directed to methods of depositing molybdenum (Mo) in high aspect ratio structures, e.g., in memory devices or logic devices, including, but not limited to, 3D-NAND, dynamic random-access memory (DRAM) cells, 3D DRAM, Fin field effect transistors (FinFET), gate-all-around (GAA) transistors, and the like. As used herein, a "high aspect ratio" structure has an aspect ratio greater than or equal to about 20:1, such as, for example, in a range of from 50:1 to 150:1. The substrates described herein, on which molybdenum (Mo) is deposited, can include at least any of the high aspect ratio structures described herein without limitation.

The embodiments of the disclosure are described by way of the Figures, which illustrate deposition methods and substrate in accordance with one or more embodiments of the disclosure. The deposition methods and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

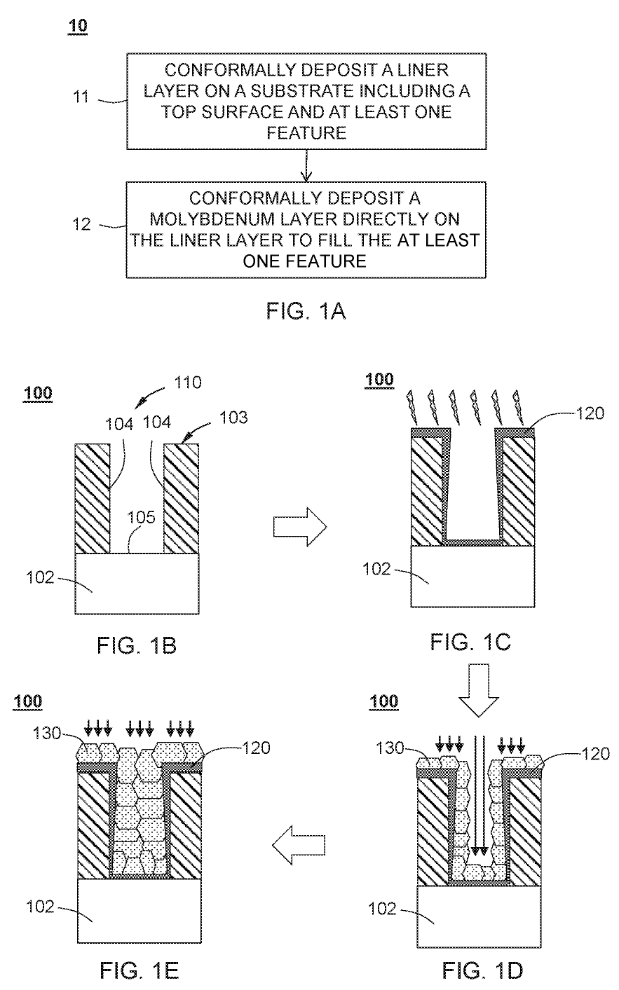

FIG. 1A illustrates a process flow diagram of a deposition method 10. FIGS. 1B–1E illustrate cross-sectional schematic views of a structure 100 (e.g., a semiconductor device) including a substrate 102 processed in accordance with the deposition method 10. The deposition method 10 comprises, consists essentially of, or consists of conformally depositing a liner layer comprising molybdenum (Mo) directly on a substrate including a top surface and at least one feature including a sidewall surface and a bottom surface (operation 11); and conformally depositing a molybdenum (Mo) layer directly on the liner layer to fill the at least one feature (operation 12).

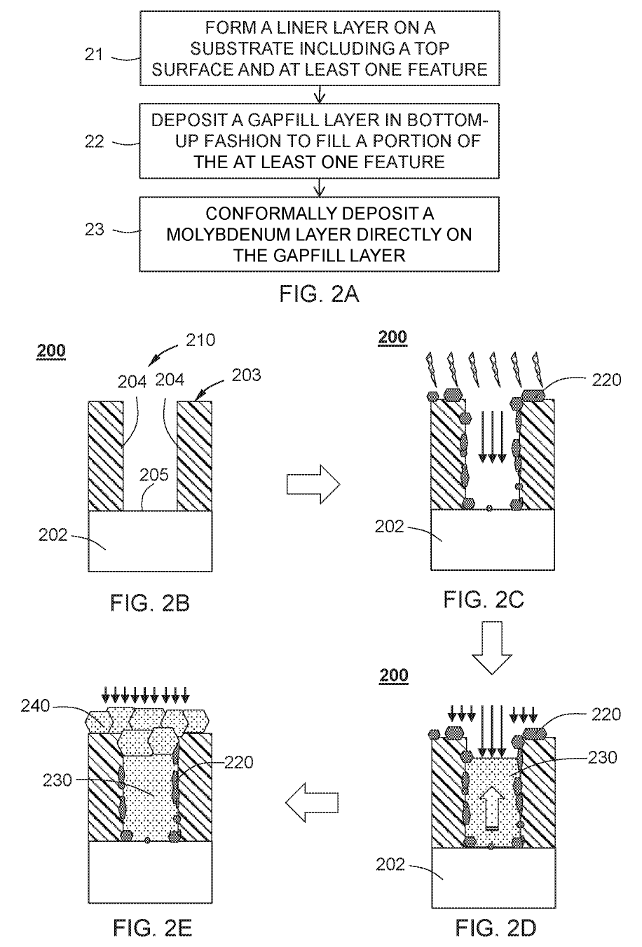

FIG. 2A illustrates a process flow diagram of a deposition method 20. FIGS. 2B–2E illustrate cross-sectional schematic views of a structure 200 (e.g., a semiconductor device) including a substrate 202 processed in accordance with the deposition method 20. The deposition method 20 comprises, consists essentially of, or consists of forming a liner layer comprising molybdenum (Mo) directly on a substrate including a top surface and at least one feature including a sidewall surface and a bottom surface (operation 21); depositing a gapfill layer comprising molybdenum (Mo) directly on the liner layer in bottom-up fashion to fill a portion of the at least one feature (operation 22); and conformally depositing a molybdenum (Mo) layer directly on the gapfill layer (operation 23).

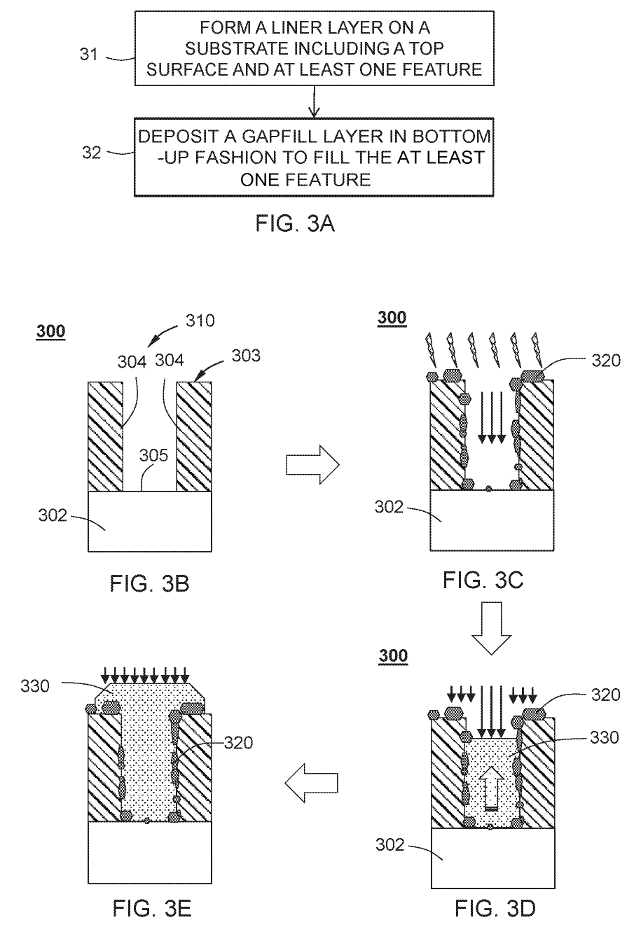

FIG. 3A illustrates a process flow diagram of a deposition method 30. FIGS. 3B–3E illustrate cross-sectional schematic views of a structure 300 (e.g., a semiconductor device) including a substrate 302 processed in accordance with the deposition method 30. The deposition method 30 comprises, consists essentially of, or consists of forming a liner layer comprising molybdenum (Mo) directly on a substrate including a top surface and at least one feature including a sidewall surface and a bottom surface (operation 31); and depositing a gapfill layer comprising molybdenum (Mo) directly on the liner layer in bottom-up fashion to fill the at least one feature (operation 32).

The methods, e.g., the deposition method 10, the deposition method 20, and the deposition method 30 can be repeated any suitable number of times. The methods, e.g., the deposition method 10, the deposition method 20, and the deposition method 30 may be performed at any suitable processing conditions, and the processing conditions may vary depending upon the application for which the substrate and the molybdenum layer(s) deposited thereon are used.

In one or more embodiments, the methods, e.g., the deposition method 10, the deposition method 20, and the deposition method 30 begin by optionally pre-treating the substrate in which the respective method is performed on. The pre-treatment can be any suitable pre-treatment known to the skilled artisan. Suitable pre-treatments include, but are not limited to, pre-heating, cleaning, soaking, or native oxide removal, as examples.

Referring to FIGS. 1A–1C, at operation 11, the deposition method 10 comprises conformally depositing a liner layer 120 comprising molybdenum (Mo) directly on a substrate 102 including a top surface 103 and at least one feature 110 including a sidewall surface 104 and a bottom surface 105. The at least one feature 110 can be any suitable feature described herein and can have any suitable aspect ratio as described herein. The skilled artisan will recognize that while a single feature is shown in FIGS. 1B–1E, the at least one feature 110 can include any suitable number of features.

The top surface 103, the sidewall surface 104, and the bottom surface 105 can independently comprise any suitable material.

In one or more embodiments, the top surface 103 comprises a metallic material. In one or more embodiments, the top surface 103 comprises molybdenum (Mo), tungsten (W), or combinations thereof. In one or more embodiments, the top surface 103 comprises molybdenum (Mo). In one or more embodiments, the top surface 103 comprises tungsten (W).

In one or more embodiments, the sidewall surface 104 comprises a dielectric material. In one or more embodiments, the sidewall surface 104 comprises a low-κ dielectric material. In one or more embodiments, the sidewall surface 104 comprises one or more of silicon oxide or silicon nitride. In one or more embodiments, the sidewall surface 104 comprises silicon oxide. In one or more embodiments, the sidewall surface 104 comprises silicon nitride.

In one or more embodiments, the bottom surface 105 comprises a metallic material. In one or more embodiments, the bottom surface 105 comprises molybdenum (Mo), tungsten (W), or combinations thereof. In one or more embodiments, the bottom surface 105 comprises molybdenum (Mo). In one or more embodiments, the bottom surface 105 comprises tungsten (W).

Referring to FIG. 1C, the liner layer 120 comprising molybdenum (Mo) is shown on the top surface 103 and along the sidewall surface 104 and the bottom surface 105. As described herein, in one or more embodiments, the liner layer 120 comprising molybdenum (Mo) is conformally deposited on the top surface 103 and along the sidewall surface 104 and the bottom surface 105 by a plasma-enhanced deposition process. In some embodiments, the plasma-enhanced deposition process is plasma-enhanced chemical vapor deposition (PECVD). In some embodiments, the plasma-enhanced deposition process is plasma-enhanced atomic layer deposition (PEALD).

In one or more embodiments, the plasma-enhanced deposition process to deposit the liner layer 120 comprises exposing the substrate 102 to a molybdenum-containing precursor, purge gas, a plasma of a reactant, and purge gas.

The molybdenum-containing precursor may be any suitable precursor that includes molybdenum (Mo). In some embodiments, the molybdenum-containing precursor comprises an organometallic precursor that includes molybdenum (Mo). In some embodiments, the molybdenum-containing precursor comprises one or more of molybdenum boride (MoB), molybdenum pentachloride (MoCl₅), molybdenum hexachloride (MoCl₆), molybdenum dioxide dichloride (MoO₂Cl₂), molybdenum oxytetrachloride (MoOCl₄), molybdenum hexafluoride (MoF₆), molybdenum hexacarbonyl, bis(tert-butylimido)-bis(dimethylamido)molybdenum, bis(ethylbenzene) molybdenum, or Bis(1-methylbenzene)molybdenum.

In some embodiments, the molybdenum-containing precursor comprises molybdenum boride (MoB). In some embodiments, the molybdenum-containing precursor comprises molybdenum pentachloride (MoCl₅). In some embodiments, the molybdenum-containing precursor comprises molybdenum hexachloride (MoCl₆). In some embodiments, the molybdenum-containing precursor comprises molybdenum dioxide dichloride (MoO₂Cl₂). In some embodiments, the molybdenum-containing precursor comprises molybdenum oxytetrachloride (MoOCl₄). In some embodiments, the molybdenum-containing precursor comprises molybdenum hexafluoride (MoF₆). In some embodiments, the molybdenum-containing precursor comprises molybdenum hexacarbonyl. In some embodiments, the molybdenum-containing precursor comprises bis(tert-butylimido)-bis(dimethylamido)molybdenum. In some embodiments, the molybdenum-containing precursor comprises bis(ethylbenzene) molybdenum. In some embodiments, the molybdenum-containing precursor comprises Bis(1-methylbenzene)molybdenum.

The reactant may include any suitable reactant that reacts with the molybdenum-containing precursor to form a pure molybdenum-containing layer, e.g., the liner layer 120. As used herein, a "pure molybdenum-containing layer" is a layer that comprises greater than or equal to about 95%, 98%, 99%, 99.5%, or 99.9% molybdenum (Mo), on an atomic basis.

In some embodiments, the plasma is formed from the reactant, i.e., one or more of hydrogen (H₂), nitrogen (N₂), or a silane (SiₓH_{y}). The plasma may include one or more of hydrogen (H₂) ions and/or radicals, nitrogen (N₂) ions and/or radicals, or silane (SiₓH_{y}) ions and/or radicals. The plasma may be an in situ plasma or an ex situ plasma. In some embodiments, the plasma is an ex situ plasma formed from hydrogen (H₂) ions. It has been advantageously found that, in specific embodiments where the plasma is an ex situ plasma formed from hydrogen (H₂) ions, resistivity of the deposited molybdenum film is reduced compared to a molybdenum film that is treated with a plasma formed from hydrogen (H₂) radicals.

In some embodiments, the plasma is formed from the reactant, i.e., one or more of hydrogen (H₂), nitrogen (N₂), or a silane (SiₓH_{y}) and a non-reactive species, such as, for example, an inert gas.

In one or more embodiments, any suitable plasma source, including, but not limited to a remote plasma source, an inductively coupled plasma (ICP) source, a capacitively coupled plasma (CCP) source, or a microwave plasma source, may be used to generate any of the disclosed plasmas and/or plasma mixtures.

The skilled artisan will appreciate that any remote plasma source, inductively coupled plasma (ICP) source, capacitively coupled plasma source (CCP) source, or microwave plasma source that is suitable for generating any of the disclosed plasmas and/or plasma mixtures and may be implemented for the disclosed methods.

The liner layer 120 may have any suitable thickness greater than or equal to 50 Å. In some embodiments, the liner layer 120 has a thickness in a range of from 50 Å to 250 Å. In one or more embodiments, the liner layer 120 is continuous.

In one or more embodiments, operation 11 may be performed at any suitable processing conditions, and the processing conditions may vary depending upon the application for which the substrate and the molybdenum layer(s) deposited thereon are used.

The liner layer 120 can be deposited at any suitable temperature and any suitable pressure. In one or more embodiments, in accordance with operation 11, the liner layer 120 is deposited at a temperature in a range of from 250 °C to 700 °C. In one or more embodiments, in accordance with operation 11, the liner layer 120 is deposited at a pressure in a range of from 2 Torr to 30 Torr.

In one or more embodiments, in accordance with operation 11, the molybdenum-containing precursor is flowed at a flow rate in a range of from 100 sccm to 2000 sccm to deposit the liner layer 120.

In one or more embodiments, in accordance with operation 11, the plasma of the reactant is generated at a plasma power in a range of 200 watts to 1500 watts during deposition of the liner layer 120.

In one or more embodiments, in accordance with operation 11, the reactant is flowed at a flow rate in a range of from 300 sccm to 20000 sccm to deposit the liner layer 120. In one or more embodiments, in accordance with operation 11, the substrate 102 is exposed to the plasma of the reactant for a time period in a range of from 1 second to 30 seconds during deposition of the liner layer 120.

In one or more embodiments, in accordance with operation 11, the substrate 102 is exposed to the plasma of the reactant for a time period in a range of from 1 second to 30 seconds during deposition of the liner layer 120.

In one or more embodiments, in accordance with operation 11, the substrate 102 is exposed to the purge gas for a time period in a range of from 0 seconds to 30 seconds during deposition of the liner layer 120. In one or more embodiments, in accordance with operation 11 where the substrate 102 is exposed to the purge gas more than once during deposition of the liner layer 120, the substrate 102 can be exposed to the purge gas each time for a time period in a range of from 0 seconds to 30 seconds, or the substrate 102 can be exposed to the purge gas for a total time period in a range of from 0 seconds to 30 seconds.

Referring to FIGS. 1A, 1D, and 1E, at operation 12, the deposition method 10 comprises conformally depositing a molybdenum (Mo) layer 130 directly on the liner layer 120 to fill the at least one feature 110.

The molybdenum (Mo) layer 130 can be deposited directly on the liner layer 120 by any suitable deposition technique. In some embodiments, conformally depositing the molybdenum (Mo) layer 130 comprises a thermal chemical vapor deposition (CVD) process. In one or more embodiments, the molybdenum (Mo) layer 130 and the liner layer 120 are formed using the same molybdenum-containing precursor. In one or more embodiments, the molybdenum (Mo) layer 130 and the liner layer 120 are formed using different molybdenum-containing precursors.

In specific embodiments, conformally depositing the molybdenum (Mo) layer 130 comprises a thermal chemical vapor deposition (CVD) process sequence of: exposure to molybdenum-containing precursor, purge gas, thermal reactant, and purge gas. In specific embodiments, the thermal reactant is hydrogen (H₂).

In one or more embodiments, operation 12 may be performed at any suitable processing conditions, and the processing conditions may vary depending upon the application for which the substrate and the molybdenum layer(s) deposited thereon are used.

The molybdenum (Mo) layer 130 can be deposited at any suitable temperature and any suitable pressure. In one or more embodiments, in accordance with operation 12, the molybdenum (Mo) layer 130 is deposited at a temperature in a range of from 250 °C to 700 °C. In one or more embodiments, in accordance with operation 12, the molybdenum (Mo) layer 130 is deposited at a pressure in a range of from 2 Torr to 30 Torr.

In one or more embodiments, in accordance with operation 12, the molybdenum-containing precursor is flowed at a flow rate in a range of from 100 sccm to 2000 sccm to deposit the molybdenum (Mo) layer 130.

In one or more embodiments, in accordance with operation 12, the thermal reactant is flowed at a flow rate in a range of from 300 sccm to 20000 sccm to deposit the molybdenum (Mo) layer 130.

In one or more embodiments, in accordance with operation 12, the substrate 102 is exposed to the purge gas for a time period in a range of from 0 seconds to 30 seconds during deposition of the molybdenum (Mo) layer 130. In one or more embodiments, in accordance with operation 12 where the substrate 102 is exposed to the purge gas more than once during deposition of the molybdenum (Mo) layer 130, the substrate 102 can be exposed to the purge gas each time for a time period in a range of from 0 seconds to 30 seconds, or the substrate 102 can be exposed to the purge gas for a total time period in a range of from 0 seconds to 30 seconds.

Referring to FIG. 1D, the molybdenum (Mo) layer 130 fills a portion of the at least one feature 110. Referring to FIG. 1E, the molybdenum (Mo) layer 130 fills the entirety of the at least one feature 110. In one or more embodiments, the molybdenum (Mo) layer 130 is deposited on the top surface 103.

In one or more embodiments, the molybdenum (Mo) layer 130 is substantially free of seams and/or voids or free of seams and/or voids. As used in this regard, "substantially free of seams and/or voids" means that less than about 5%, including less than about 4%, less than about 3%, less than about 2%, less than about 1%, less than about 0.5%, and less than about 0.1% of the total composition of the molybdenum (Mo) layer 130 an atomic basis, comprises seams and/or voids. In one or more embodiments, the molybdenum (Mo) layer 130 is free of seams and/or voids.

Advantageously, the deposition method 10 is configured to provide improved step coverage compared to conventional molybdenum deposition processes as described herein. Advantageously, the deposition method 10 is configured to provide molybdenum films having better crystallinity and lower O/Cl impurities compared to conventional PECVD methods.

Referring to FIGS. 2A–2C, at operation 21, the deposition method 20 comprises forming a liner layer 220 comprising molybdenum (Mo) directly on a substrate 202 including a top surface 203 and at least one feature 210 including a sidewall surface 204 and a bottom surface 205. The at least one feature 210 can be any suitable feature described herein and can have any suitable aspect ratio as described herein. The skilled artisan will recognize that while a single feature is shown in FIGS. 2B–2E, the at least one feature 210 can include any suitable number of features.

The top surface 203, the sidewall surface 204, and the bottom surface 205 can independently comprise any suitable material.

In one or more embodiments, the top surface 203 comprises a metallic material. In one or more embodiments, the top surface 203 comprises molybdenum (Mo), tungsten (W), or combinations thereof. In one or more embodiments, the top surface 203 comprises molybdenum (Mo). In one or more embodiments, the top surface 203 comprises tungsten (W).

In one or more embodiments, the sidewall surface 204 comprises a dielectric material. In one or more embodiments, the sidewall surface 204 comprises a low-κ dielectric material. In one or more embodiments, the sidewall surface 204 comprises one or more of silicon oxide or silicon nitride. In one or more embodiments, the sidewall surface 204 comprises silicon oxide. In one or more embodiments, the sidewall surface 204 comprises silicon nitride.

In one or more embodiments, the bottom surface 205 comprises a metallic material. In one or more embodiments, the bottom surface 205 comprises molybdenum (Mo), tungsten (W), or combinations thereof. In one or more embodiments, the bottom surface 205 comprises molybdenum (Mo). In one or more embodiments, the bottom surface 205 comprises tungsten (W).

Referring to FIG. 2C, the liner layer 220 comprising molybdenum (Mo) is shown on the top surface 203, the sidewall surface 204, and the bottom surface 205. As described herein, in one or more embodiments, the liner layer 220 comprising molybdenum (Mo) is formed by a plasma-enhanced deposition process. In some embodiments, the plasma-enhanced deposition process is plasma-enhanced chemical vapor deposition (PECVD). In some embodiments, the plasma-enhanced deposition process is plasma-enhanced atomic layer deposition (PEALD).

In one or more embodiments, the plasma-enhanced deposition process to deposit the liner layer 220 comprises exposing the substrate 202 to a molybdenum-containing precursor, purge gas, a plasma of a reactant, and purge gas.

The molybdenum-containing precursor may be any suitable precursor that includes molybdenum (Mo). In some embodiments, the molybdenum-containing precursor comprises an organometallic precursor that includes molybdenum (Mo). In some embodiments, the molybdenum-containing precursor comprises one or more of molybdenum boride (MoB), molybdenum pentachloride (MoCl₅), molybdenum hexachloride (MoCl₆), molybdenum dioxide dichloride (MoO₂Cl₂), molybdenum oxytetrachloride (MoOCl₄), molybdenum hexafluoride (MoF₆), molybdenum hexacarbonyl, bis(tert-butylimido)-bis(dimethylamido)molybdenum, bis(ethylbenzene) molybdenum, or Bis(1-methylbenzene)molybdenum.

In some embodiments, the molybdenum-containing precursor comprises molybdenum boride (MoB). In some embodiments, the molybdenum-containing precursor comprises molybdenum pentachloride (MoCl₅). In some embodiments, the molybdenum-containing precursor comprises molybdenum hexachloride (MoCl₆). In some embodiments, the molybdenum-containing precursor comprises molybdenum dioxide dichloride (MoO₂Cl₂). In some embodiments, the molybdenum-containing precursor comprises molybdenum oxytetrachloride (MoOCl₄). In some embodiments, the molybdenum-containing precursor comprises molybdenum hexafluoride (MoF₆). In some embodiments, the molybdenum-containing precursor comprises molybdenum hexacarbonyl. In some embodiments, the molybdenum-containing precursor comprises bis(tert-butylimido)-bis(dimethylamido)molybdenum. In some embodiments, the molybdenum-containing precursor comprises bis(ethylbenzene) molybdenum. In some embodiments, the molybdenum-containing precursor comprises Bis(1-methylbenzene)molybdenum.

The reactant may include any suitable reactant that reacts with the molybdenum-containing precursor to form a pure molybdenum-containing layer, e.g., the liner layer 220. As used herein, a "pure molybdenum-containing layer" is a layer that comprises greater than or equal to about 95%, 98%, 99%, 99.5%, or 99.9% molybdenum (Mo), on an atomic basis.

In some embodiments, the plasma is formed from the reactant, i.e., one or more of hydrogen (H₂), nitrogen (N₂), or a silane (SiₓH_{y}). The plasma may include one or more of hydrogen (H₂) ions and/or radicals, nitrogen (N₂) ions and/or radicals, or silane (SiₓH_{y}) ions and/or radicals. The plasma may be an in situ plasma or an ex situ plasma. In some embodiments, the plasma is an ex situ plasma formed from hydrogen (H₂) ions. It has been advantageously found that, in specific embodiments where the plasma is an ex situ plasma formed from hydrogen (H₂) ions, resistivity of the deposited molybdenum film is reduced compared to a molybdenum film that is treated with a plasma formed from hydrogen (H₂) radicals.

In some embodiments, the plasma is formed from the reactant, i.e., one or more of hydrogen (H₂), nitrogen (N₂), or a silane (SiₓH_{y}) and a non-reactive species, such as, for example, an inert gas.

In one or more embodiments, any suitable plasma source, including, but not limited to a remote plasma source, an inductively coupled plasma (ICP) source, a capacitively coupled plasma (CCP) source, or a microwave plasma source, may be used to generate any of the disclosed plasmas and/or plasma mixtures.

The skilled artisan will appreciate that any remote plasma source, inductively coupled plasma (ICP) source, capacitively coupled plasma source (CCP) source, or microwave plasma source that is suitable for generating any of the disclosed plasmas and/or plasma mixtures and may be implemented for the disclosed methods.

The liner layer 220 may have any suitable thickness in a range of from 15 Å to less than 50 Å. In some embodiments, the liner layer 220 has a thickness in a range of from 15 Å to 40 Å. In some embodiments, the liner layer 220 has a thickness of 15 Å. In some embodiments, the liner layer 220 has a thickness of 40 Å. In some embodiments, the liner layer 220 has a thickness of 50 Å.

In one or more embodiments, operation 21 may be performed at any suitable processing conditions, and the processing conditions may vary depending upon the application for which the substrate and the molybdenum layer(s) deposited thereon are used.

The liner layer 220 can be deposited at any suitable temperature and any suitable pressure. In one or more embodiments, in accordance with operation 21, the liner layer 220 is deposited at a temperature in a range of from 250 °C to 700 °C. In one or more embodiments, in accordance with operation 21, the liner layer 220 is deposited at a pressure in a range of from 2 Torr to 30 Torr.

In one or more embodiments, in accordance with operation 21, the molybdenum-containing precursor is flowed at a flow rate in a range of from 100 sccm to 2000 sccm to deposit the liner layer 220.

In one or more embodiments, in accordance with operation 21, the plasma of the reactant is generated at a plasma power in a range of 200 watts to 1500 watts during deposition of the liner layer 220.

In one or more embodiments, in accordance with operation 21, the reactant is flowed at a flow rate in a range of from 300 sccm to 20000 sccm to deposit the liner layer 220. In one or more embodiments, in accordance with operation 21, the substrate 202 is exposed to the plasma of the reactant for a time period in a range of from 1 second to 30 seconds during deposition of the liner layer 220.

In one or more embodiments, in accordance with operation 21, the substrate 202 is exposed to the plasma of the reactant for a time period in a range of from 1 second to 30 seconds during deposition of the liner layer 220.

In one or more embodiments, in accordance with operation 21, the substrate 202 is exposed to the purge gas for a time period in a range of from 0 seconds to 30 seconds during deposition of the liner layer 220. In one or more embodiments, in accordance with operation 21 where the substrate 202 is exposed to the purge gas more than once during deposition of the liner layer 220, the substrate 202 can be exposed to the purge gas each time for a time period in a range of from 0 seconds to 30 seconds, or the substrate 202 can be exposed to the purge gas for a total time period in a range of from 0 seconds to 30 seconds.

Referring to FIGS. 2A and 2D, at operation 22, the deposition method 20 comprises depositing a gapfill layer 230 comprising molybdenum (Mo) directly on the liner layer 220 in bottom-up fashion to fill a portion of the at least one feature 210.

The gapfill layer 230 can be deposited in bottom-up fashion to fill a portion of the at least one feature 210 by any suitable deposition technique. In some embodiments, depositing the gapfill layer 230 comprises a thermal chemical vapor deposition (CVD) process. In one or more embodiments, the gapfill layer 230 and the liner layer 220 are formed using the same molybdenum-containing precursor. In one or more embodiments, the gapfill layer 230 and the liner layer 220 are formed using different molybdenum-containing precursors.

In one or more embodiments, the gapfill layer 230 selectively grows on the bottom surface 205, forming a single-crystal grain with ultra-low resistivity. In one or more embodiments, after overcoming incubation delay, polycrystalline molybdenum starts forming on the sidewall surface 204. Advantageously, the growth of the gapfill layer 230 prevents step-coverage issues of conventional PECVD processes.

In one or more embodiments, operation 22 may be performed at any suitable processing conditions, and the processing conditions may vary depending upon the application for which the substrate and the molybdenum layer(s) deposited thereon are used.

The gapfill layer 230 can be deposited at any suitable temperature and any suitable pressure. In one or more embodiments, in accordance with operation 22, the gapfill layer 230 is deposited at a temperature in a range of from 250 °C to 700 °C. In one or more embodiments, in accordance with operation 22, the gapfill layer 230 is deposited at a pressure in a range of from 2 Torr to 30 Torr.

In one or more embodiments, in accordance with operation 22, the molybdenum-containing precursor is flowed at a flow rate in a range of from 100 sccm to 2000 sccm to deposit the gapfill layer 230.

In one or more embodiments, in accordance with operation 22, the thermal reactant is flowed at a flow rate in a range of from 300 sccm to 20000 sccm to deposit the gapfill layer 230.

In one or more embodiments, in accordance with operation 22, the substrate 202 is exposed to the purge gas for a time period in a range of from 0 seconds to 30 seconds during deposition of the gapfill layer 230. In one or more embodiments, in accordance with operation 22 where the substrate 202 is exposed to the purge gas more than once during deposition of the gapfill layer 230, the substrate 202 can be exposed to the purge gas each time for a time period in a range of from 0 seconds to 30 seconds, or the substrate 202 can be exposed to the purge gas for a total time period in a range of from 0 seconds to 30 seconds.

In one or more embodiments, the gapfill layer 230 is substantially free of seams and/or voids or free of seams and/or voids. As used in this regard, "substantially free of seams and/or voids" means that less than about 5%, including less than about 4%, less than about 3%, less than about 2%, less than about 1%, less than about 0.5%, and less than about 0.1% of the total composition of the gapfill layer 230 an atomic basis, comprises seams and/or voids. In one or more embodiments, the gapfill layer 230 is free of seams and/or voids.

Referring to FIGS. 2A and 2E, at operation 23, the deposition method 20 comprises conformally depositing a molybdenum (Mo) layer 240 directly on the gapfill layer 230.

The molybdenum (Mo) layer 240 can be deposited directly on the gapfill layer 230 by any suitable deposition technique. In some embodiments, conformally depositing the molybdenum (Mo) layer 130 comprises a thermal chemical vapor deposition (CVD) process. In one or more embodiments, the molybdenum (Mo) layer 240, the gapfill layer 230, and the liner layer 220 are formed using the same molybdenum-containing precursor. In one or more embodiments, one or more of the molybdenum (Mo) layer 240, the gapfill layer 230, and the liner layer 220 are formed using different molybdenum-containing precursors.

In FIG. 2D, the gapfill layer 230 fills a portion of the at least one feature 210. In FIG. 2E, the molybdenum (Mo) layer 240 is shown as being conformally deposited directly on the gapfill layer 230 and on the top surface 203. In FIG. 2E, the molybdenum (Mo) layer 240 fills the remaining portion of the at least one feature 210. In FIG. 2E, in one or more embodiments, the molybdenum (Mo) layer 240 and the gapfill layer 230 collectively fill the entirety of the at least one feature 210.

In one or more embodiments, operation 23 may be performed at any suitable processing conditions, and the processing conditions may vary depending upon the application for which the substrate and the molybdenum layer(s) deposited thereon are used.

The molybdenum (Mo) layer 240 can be deposited at any suitable temperature and any suitable pressure. In one or more embodiments, in accordance with operation 23, the molybdenum (Mo) layer 240 is deposited at a temperature in a range of from 250 °C to 700 °C. In one or more embodiments, in accordance with operation 23, the molybdenum (Mo) layer 240 is deposited at a pressure in a range of from 2 Torr to 30 Torr.

In one or more embodiments, in accordance with operation 23, the molybdenum-containing precursor is flowed at a flow rate in a range of from 100 sccm to 2000 sccm to deposit the molybdenum (Mo) layer 240.

In one or more embodiments, in accordance with operation 23, the thermal reactant is flowed at a flow rate in a range of from 300 sccm to 20000 sccm to deposit the molybdenum (Mo) layer 240.

In one or more embodiments, in accordance with operation 23, the substrate 202 is exposed to the purge gas for a time period in a range of from 0 seconds to 30 seconds during deposition of the molybdenum (Mo) layer 240. In one or more embodiments, in accordance with operation 23 where the substrate 202 is exposed to the purge gas more than once during deposition of the molybdenum (Mo) layer 240, the substrate 202 can be exposed to the purge gas each time for a time period in a range of from 0 seconds to 30 seconds, or the substrate 202 can be exposed to the purge gas for a total time period in a range of from 0 seconds to 30 seconds.

In one or more embodiments, the molybdenum (Mo) layer 240 is substantially free of seams and/or voids or free of seams and/or voids. As used in this regard, "substantially free of seams and/or voids" means that less than about 5%, including less than about 4%, less than about 3%, less than about 2%, less than about 1%, less than about 0.5%, and less than about 0.1% of the total composition of the molybdenum (Mo) layer 240 an atomic basis, comprises seams and/or voids. In one or more embodiments, the molybdenum (Mo) layer 240 is free of seams and/or voids.

Advantageously, the deposition method 20 is configured to provide low contact resistivity molybdenum deposition with improved grain connectivity.

Referring to FIGS. 3A–3C, at operation 31, the deposition method 30 comprises forming a liner layer 320 comprising molybdenum (Mo) directly on a substrate 302 including a top surface 303 and at least one feature 310 including a sidewall surface 304 and a bottom surface 305. The at least one feature 310 can be any suitable feature described herein and can have any suitable aspect ratio as described herein. The skilled artisan will recognize that while a single feature is shown in FIGS. 3B–3E, the at least one feature 310 can include any suitable number of features.

The top surface 303, the sidewall surface 304, and the bottom surface 305 can independently comprise any suitable material.

In one or more embodiments, the top surface 303 comprises a metallic material. In one or more embodiments, the top surface 303 comprises molybdenum (Mo), tungsten (W), or combinations thereof. In one or more embodiments, the top surface 303 comprises molybdenum (Mo). In one or more embodiments, the top surface 303 comprises tungsten (W).

In one or more embodiments, the sidewall surface 304 comprises a dielectric material. In one or more embodiments, the sidewall surface 304 comprises a low-κ dielectric material. In one or more embodiments, the sidewall surface 304 comprises one or more of silicon oxide or silicon nitride. In one or more embodiments, the sidewall surface 304 comprises silicon oxide. In one or more embodiments, the sidewall surface 304 comprises silicon nitride.

In one or more embodiments, the bottom surface 305 comprises a metallic material. In one or more embodiments, the bottom surface 305 comprises molybdenum (Mo), tungsten (W), or combinations thereof. In one or more embodiments, the bottom surface 305 comprises molybdenum (Mo). In one or more embodiments, the bottom surface 305 comprises tungsten (W).

Referring to FIG. 3C, the liner layer 320 comprising molybdenum (Mo) is shown on the top surface 303, the sidewall surface 304, and the bottom surface 305. As described herein, in one or more embodiments, the liner layer 320 comprising molybdenum (Mo) is formed by a plasma-enhanced deposition process. In some embodiments, the plasma-enhanced deposition process is plasma-enhanced chemical vapor deposition (PECVD). In some embodiments, the plasma-enhanced deposition process is plasma-enhanced atomic layer deposition (PEALD).

In one or more embodiments, the plasma-enhanced deposition process to deposit the liner layer 320 comprises exposing the substrate 302 to a molybdenum-containing precursor, purge gas, a plasma of a reactant, and purge gas.

The molybdenum-containing precursor may be any suitable precursor that includes molybdenum (Mo). In some embodiments, the molybdenum-containing precursor comprises an organometallic precursor that includes molybdenum (Mo). In some embodiments, the molybdenum-containing precursor comprises one or more of molybdenum boride (MoB), molybdenum pentachloride (MoCl₅), molybdenum hexachloride (MoCl₆), molybdenum dioxide dichloride (MoO₂Cl₂), molybdenum oxytetrachloride (MoOCl₄), molybdenum hexafluoride (MoF₆), molybdenum hexacarbonyl, bis(tert-butylimido)-bis(dimethylamido)molybdenum, bis(ethylbenzene) molybdenum, or Bis(1-methylbenzene)molybdenum.

In some embodiments, the molybdenum-containing precursor comprises molybdenum boride (MoB). In some embodiments, the molybdenum-containing precursor comprises molybdenum pentachloride (MoCl₅). In some embodiments, the molybdenum-containing precursor comprises molybdenum hexachloride (MoCl₆). In some embodiments, the molybdenum-containing precursor comprises molybdenum dioxide dichloride (MoO₂Cl₂). In some embodiments, the molybdenum-containing precursor comprises molybdenum oxytetrachloride (MoOCl₄). In some embodiments, the molybdenum-containing precursor comprises molybdenum hexafluoride (MoF₆). In some embodiments, the molybdenum-containing precursor comprises molybdenum hexacarbonyl. In some embodiments, the molybdenum-containing precursor comprises bis(tert-butylimido)-bis(dimethylamido)molybdenum. In some embodiments, the molybdenum-containing precursor comprises bis(ethylbenzene) molybdenum. In some embodiments, the molybdenum-containing precursor comprises Bis(1-methylbenzene)molybdenum.

The reactant may include any suitable reactant that reacts with the molybdenum-containing precursor to form a pure molybdenum-containing layer, e.g., the liner layer 320. As used herein, a "pure molybdenum-containing layer" is a layer that comprises greater than or equal to about 95%, 98%, 99%, 99.5%, or 99.9% molybdenum (Mo), on an atomic basis. In one or more embodiments, the reactant comprises hydrogen (H₂).

In some embodiments, the plasma is formed from the reactant, i.e., one or more of hydrogen (H₂), nitrogen (N₂), or a silane (SiₓH_{y}). The plasma may include one or more of hydrogen (H₂) ions and/or radicals, nitrogen (N₂) ions and/or radicals, or silane (SiₓH_{y}) ions and/or radicals. The plasma may be an in situ plasma or an ex situ plasma. In some embodiments, the plasma is an ex situ plasma formed from hydrogen (H₂) ions. It has been advantageously found that, in specific embodiments where the plasma is an ex situ plasma formed from hydrogen (H₂) ions, resistivity of the deposited molybdenum film is reduced compared to a molybdenum film that is treated with a plasma formed from hydrogen (H₂) radicals.

In some embodiments, the plasma is formed from the reactant, i.e., one or more of hydrogen (H₂), nitrogen (N₂), or a silane (SiₓH_{y}) and a non-reactive species, such as, for example, an inert gas.

In one or more embodiments, any suitable plasma source, including, but not limited to a remote plasma source, an inductively coupled plasma (ICP) source, a capacitively coupled plasma (CCP) source, or a microwave plasma source, may be used to generate any of the disclosed plasmas and/or plasma mixtures.

The skilled artisan will appreciate that any remote plasma source, inductively coupled plasma (ICP) source, capacitively coupled plasma source (CCP) source, or microwave plasma source that is suitable for generating any of the disclosed plasmas and/or plasma mixtures and may be implemented for the disclosed methods.

The liner layer 320 may have any suitable thickness less than 15 Å. In some embodiments, the liner layer 320 has a thickness less than or equal to 10 Å. In some embodiments, the liner layer 320 has a thickness in a range of from 2 Å to 6 Å. In some embodiments, the liner layer 320 has a thickness 2 Å, 3 Å, 4 Å, 5 Å, or 6 Å.

In one or more embodiments, operation 31 may be performed at any suitable processing conditions, and the processing conditions may vary depending upon the application for which the substrate and the molybdenum layer(s) deposited thereon are used.

The liner layer 320 can be deposited at any suitable temperature and any suitable pressure. In one or more embodiments, in accordance with operation 31, the liner layer 320 is deposited at a temperature in a range of from 250 °C to 700 °C. In one or more embodiments, in accordance with operation 31, the liner layer 320 is deposited at a pressure in a range of from 2 Torr to 30 Torr.

In one or more embodiments, in accordance with operation 31, the molybdenum-containing precursor is flowed at a flow rate in a range of from 100 sccm to 2000 sccm to deposit the liner layer 320.

In one or more embodiments, in accordance with operation 31, the plasma of the reactant is generated at a plasma power in a range of 200 watts to 1500 watts during deposition of the liner layer 320.

In one or more embodiments, in accordance with operation 31, the reactant is flowed at a flow rate in a range of from 300 sccm to 20000 sccm to deposit the liner layer 320. In one or more embodiments, in accordance with operation 31, the substrate 302 is exposed to the plasma of the reactant for a time period in a range of from 1 second to 30 seconds during deposition of the liner layer 320.

In one or more embodiments, in accordance with operation 31, the substrate 302 is exposed to the plasma of the reactant for a time period in a range of from 1 second to 30 seconds during deposition of the liner layer 320.

In one or more embodiments, in accordance with operation 31, the substrate 302 is exposed to the purge gas for a time period in a range of from 0 seconds to 30 seconds during deposition of the liner layer 320. In one or more embodiments, in accordance with operation 31 where the substrate 302 is exposed to the purge gas more than once during deposition of the liner layer 320, the substrate 302 can be exposed to the purge gas each time for a time period in a range of from 0 seconds to 30 seconds, or the substrate 302 can be exposed to the purge gas for a total time period in a range of from 0 seconds to 30 seconds.

Referring to FIGS. 3A, 3D, and 3E, at operation 32, the deposition method 30 comprises depositing a gapfill layer 330 comprising molybdenum (Mo) directly on the liner layer 320 in bottom-up fashion to fill the at least one feature 310.

The gapfill layer 330 can be deposited in bottom-up fashion to fill the at least one feature 310 by any suitable deposition technique. In some embodiments, depositing the gapfill layer 330 comprises a thermal chemical vapor deposition (CVD) process. In one or more embodiments, the gapfill layer 330 and the liner layer 320 are formed using the same molybdenum-containing precursor. In one or more embodiments, the gapfill layer 330 and the liner layer 320 are formed using different molybdenum-containing precursors.

In one or more embodiments, the gapfill layer 330 selectively grows on the bottom surface 305, forming a single-crystal grain with ultra-low resistivity. In one or more embodiments, the gapfill layer 330 selectively grows on the bottom surface 305 at a selectivity ratio of 1:100 (bottom surface 305:sidewall surface 304). In one or more embodiments, the gapfill layer 330 does not form on the sidewall surface 304.

In one or more embodiments, operation 32 may be performed at any suitable processing conditions, and the processing conditions may vary depending upon the application for which the substrate and the molybdenum layer(s) deposited thereon are used.

The gapfill layer 330 can be deposited at any suitable temperature and any suitable pressure. In one or more embodiments, in accordance with operation 32, the gapfill layer 330 is deposited at a temperature in a range of from 250 °C to 700 °C. In one or more embodiments, in accordance with operation 32, the gapfill layer 330 is deposited at a pressure in a range of from 2 Torr to 30 Torr.

In one or more embodiments, in accordance with operation 32, the molybdenum-containing precursor is flowed at a flow rate in a range of from 100 sccm to 2000 sccm to deposit the gapfill layer 330.

In one or more embodiments, in accordance with operation 32, the thermal reactant is flowed at a flow rate in a range of from 300 sccm to 20000 sccm to deposit the gapfill layer 330.

In one or more embodiments, in accordance with operation 32, the substrate 302 is exposed to the purge gas for a time period in a range of from 0 seconds to 30 seconds during deposition of the gapfill layer 330. In one or more embodiments, in accordance with operation 32 where the substrate 302 is exposed to the purge gas more than once during deposition of the gapfill layer 330, the substrate 302 can be exposed to the purge gas each time for a time period in a range of from 0 seconds to 30 seconds, or the substrate 302 can be exposed to the purge gas for a total time period in a range of from 0 seconds to 30 seconds.

Referring to FIG. 3D, the gapfill layer 330 fills a portion of the at least one feature 310. Referring to FIG. 3E, the gapfill layer 330 fills the entirety of the at least one feature 310.

In one or more embodiments, the gapfill layer 330 does not form on the sidewall surface 304. In one or more embodiments, the gapfill layer 330 does not form on the sidewall surface 304 and is substantially free of seams and/or voids or free of seams and/or voids. As used in this regard, "substantially free of seams and/or voids" means that less than about 5%, including less than about 4%, less than about 3%, less than about 2%, less than about 1%, less than about 0.5%, and less than about 0.1% of the total composition of the gapfill layer 330 an atomic basis, comprises seams and/or voids. In one or more embodiments, the gapfill layer 330 is free of seams and/or voids.

In one or more embodiments, the gapfill layer 330 fills the entirety of the at least one feature 310 and forms on the top surface 303. In one or more embodiments, the gapfill layer 330 defines a “flat mushroom shape” on the top surface 303. Advantageously, etching the flat mushroom shape, i.e., the gapfill layer 330 on the top surface 303 for use as an interconnect or contact, for example, can be completed without resultant defects in the film.

In one or more embodiments, the methods described herein (the deposition method 10, the deposition method 20, and the deposition method 30), may be used as part of a semiconductor device manufacturing and/or a microelectronic device manufacturing process. It will be appreciated by the skilled artisan that one or more subsequent operations (e.g., after the deposition method 10, the deposition method 20, and/or the deposition method 30) can be performed to complete a semiconductor device manufacturing process and/or microelectronic device manufacturing process without undue experimentation.

The methods described herein (e.g., the deposition method 10, the deposition method 20, and/or the deposition method 30) may be performed in any suitable processing chamber or processing system.

Additional embodiments of the disclosure are directed to processing tools. In some embodiments, the processing tool comprises: a central transfer station comprising a robot configured to move a substrate a plurality of processing stations, and a controller connected to the central transfer station and the plurality of processing stations. In some embodiments, each processing station is connected to the central transfer station and provides a processing region separated from processing regions of adjacent processing stations. In some embodiments, the plurality of processing stations are independently suitable for performing the deposition method 10, the deposition method 20, and/or the deposition method 30. In some embodiments, the controller is configured to activate the robot to move the substrate between processing stations, and to control the deposition method 10, the deposition method 20, and/or the deposition method 30.

One or more embodiments of the disclosure are directed to a non-transitory computer readable medium including instructions, that, when executed by a controller of a processing system, cause the processing system to perform one or more of the operations of the methods (e.g., the deposition method 10, the deposition method 20, and/or the deposition method 30) described herein.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the methods of the present disclosure without departing from the spirit and scope of the disclosure. Thus, the present disclosure can include modifications and variations that are within the scope of the appended claims and their equivalents.

What is claimed is:

1. A deposition method comprising:
conformally depositing a liner layer comprising molybdenum (Mo) directly on a substrate including a top surface and at least one feature including a sidewall surface and a bottom surface, conformally depositing the liner layer comprising a plasma-enhanced deposition process to form the liner layer on the top surface and along the sidewall surface and the bottom surface, the liner layer having a thickness of greater than or equal to 50 Å; and
conformally depositing a molybdenum (Mo) layer directly on the liner layer to fill the at least one feature, wherein conformally depositing the molybdenum (Mo) layer comprises a thermal chemical vapor deposition (CVD) process, and the molybdenum (Mo) layer is substantially free of seams and/or voids.

2. The deposition method of claim 1, wherein the sidewall surface comprises a dielectric material.

3. The deposition method of claim 1, wherein the bottom surface comprises a metallic material.

4. The deposition method of claim 3, wherein the metallic material is molybdenum (Mo) or tungsten (W).

5. The deposition method of claim 1, wherein the plasma-enhanced deposition process is plasma-enhanced chemical vapor deposition (PECVD).

6. The deposition method of claim 1, wherein the plasma-enhanced deposition process is plasma-enhanced atomic layer deposition (PEALD).

7. A deposition method comprising:
forming a liner layer comprising molybdenum (Mo) directly on a substrate including a top surface and at least one feature including a sidewall surface and a bottom surface, forming the liner layer comprising a plasma-enhanced deposition process, the liner layer having a thickness in a range of from 15 Å to less than 50 Å;
depositing a gapfill layer comprising molybdenum (Mo) directly on the liner layer in bottom-up fashion to fill a portion of the at least one feature; and
conformally depositing a molybdenum (Mo) layer directly on the gapfill layer, the molybdenum (Mo) layer formed on a top surface of the gapfill layer and on the top surface of the substrate, wherein each of the gapfill layer and the molybdenum (Mo) layer is substantially free of seams and/or voids.

8. The deposition method of claim 7, wherein the sidewall surface comprises a dielectric material.

9. The deposition method of claim 7, wherein the bottom surface comprises a metallic material.

10. The deposition method of claim 9, wherein the metallic material is molybdenum (Mo) or tungsten (W).

11. The deposition method of claim 7, wherein the plasma-enhanced deposition process is plasma-enhanced chemical vapor deposition (PECVD).

12. The deposition method of claim 7, wherein the plasma-enhanced deposition process is plasma-enhanced atomic layer deposition (PEALD).

13. A deposition method comprising:
forming a liner layer comprising molybdenum (Mo) directly on a substrate including a top surface and at least one feature including a sidewall surface and a bottom surface, forming the liner layer comprising a plasma-enhanced deposition process, the liner layer having a thickness of less than 15 Å; and
depositing a gapfill layer comprising molybdenum (Mo) directly on the liner layer in bottom-up fashion to fill the at least one feature.

14. The deposition method of claim 13, wherein the sidewall surface comprises a dielectric material.

15. The deposition method of claim 13, wherein the bottom surface comprises a metallic material.

16. The deposition method of claim 15, wherein the metallic material is molybdenum (Mo) or tungsten (W).

17. The deposition method of claim 13, wherein the plasma-enhanced deposition process is plasma-enhanced chemical vapor deposition (PECVD).

18. The deposition method of claim 13, wherein the plasma-enhanced deposition process is plasma-enhanced atomic layer deposition (PEALD).

19. The deposition method of claim 13, wherein the thickness of the liner layer is less than or equal to 10 Å.

20. The deposition method of claim 19, wherein the thickness of the liner layer is in a range of from 2 Å to 6 Å.
